(19) United States
(12) Patent Application Publication
(10) Pub. No.: US 2025/0331140 A1
(43) Pub. Date: Oct. 23, 2025

(54) COVER PLATE AND MANUFACTURING METHOD THEREOF, AND DISPLAY DEVICE

(71) Applicant: Wuhan Tianma Micro-Electronics Co., Ltd., Wuhan (CN)

(72) Inventors: Qifeng ZHU, Wuhan (CN); Yueji CHEN, Wuhan (CN); Shuxiong SONG, Wuhan (CN); Jiang CHEN, Wuhan (CN)

(21) Appl. No.: 18/799,052

(22) Filed: Aug. 9, 2024

(30) Foreign Application Priority Data
Apr. 17, 2024 (CN) 202410465294.9

(51) Int. Cl. H05K 9/00

(52) U.S. Cl. CPC H05K 9/0079; H05K 9/0054

(57) ABSTRACT

The present disclosure discloses a cover plate. The cover plate includes a substrate and an antistatic film. The antistatic film is located on a side of the substrate. The antistatic film includes a compound having a first carbon chain, and at least one carbon in the first carbon chain carries an electron-donating group.

### CROSS-REFERENCES TO RELATED APPLICATIONS

The present disclosure claims priority to Chinese Patent Application No. 202410465294.9, filed on Apr. 17, 2024, the content of which is incorporated herein by reference in its entirety.

### FIELD OF THE DISCLOSURE

The present disclosure relates to the field of display technology, and more specifically, relates to a cover plate and a manufacturing method thereof, and a display device.

### BACKGROUND

During the manufacturing and testing process of display devices, static electricity is easily generated due to friction. In addition, static electricity in the air, human body or other charged objects may also be transferred to the display device. Display devices such as mobile phones and PADs used in daily life include touch functions. When using these display devices, the touch subject frequently touches the display screen or slides a finger on the display screen. When the display screen includes static electricity, the static electricity may potentially affect the normal display of the product. If the static electricity cannot be released or is not sufficiently released, the accumulated static electricity may affect the display effect of the display panel. For example, when static electricity accumulates on the display screen, the region where static electricity accumulates on the screen may exhibit a phenomenon of local brightness and may even damage the display device.

### SUMMARY

One aspect of the present disclosure provides a cover plate. The cover plate includes a substrate and an antistatic film. The antistatic film is located on a side of the substrate. The antistatic film includes a compound having a first carbon chain, and at least one carbon in the first carbon chain carries an electron-donating group.

Another aspect of the present disclosure provides a method for manufacturing a cover plate. The method includes providing a substrate and forming an antistatic film on a side of the substrate. The antistatic film includes a compound having a first carbon chain, and at least one carbon in the first carbon chain carries an electron-donating group.

Still another aspect of the present disclosure provides a display device. The display device includes a display panel and a cover plate. The cover plate is located on a light-emitting side of the display panel, and the cover plate includes a substrate and an antistatic film. The antistatic film is located on a side of the substrate away from the display panel. The antistatic film includes a compound having a first carbon chain, and at least one carbon in the first carbon chain carries an electron-donating group.

### BRIEF DESCRIPTION OF THE DRAWINGS

The accompanying drawings incorporated in the specification and constituting a part of the specification illustrate embodiments of the present disclosure, and, together with the description, serve to explain the principles of the present disclosure.

FIG. 1 is a schematic diagram of a display device.

FIG. 2 is a schematic diagram of the principle of defect cause analysis.

FIG. 3 is a schematic structural diagram of a cover plate provided by the present disclosure.

FIG. 4 is a schematic diagram of a state where a compound having a first carbon chain is adsorbed on the surface of a substrate.

FIG. 5 is a simulation test diagram of a cover plate provided by the present disclosure after a copper rod friction test.

FIG. 6 is a schematic diagram of another state where a compound having a first carbon chain is adsorbed on the surface of a substrate.

FIG. 7 is a schematic diagram of yet another state where a compound having a first carbon chain is adsorbed on the surface of a substrate.

FIG. 8 is a schematic diagram of yet another state where a compound having a first carbon chain is adsorbed on the surface of a substrate.

FIG. 9 is a schematic diagram of a state where a compound having a first carbon chain and a compound having a second carbon chain are adsorbed on the surface of a substrate.

FIG. 10 is a schematic structural diagram of another cover plate provided by the present disclosure.

FIG. 11 is a flowchart of a method for manufacturing a cover plate provided by the present disclosure.

FIG. 12 is a flowchart of forming an antistatic film on a side of a substrate in a method for manufacturing a cover plate provided by the present disclosure.

FIG. 13 is a flowchart of evaporating a stock solution onto a side of a substrate to form an antistatic film in a method for manufacturing a cover plate provided by the present disclosure.

FIG. 14 is a schematic diagram of the process of evaporating a stock solution onto a side of a substrate to form an antistatic film.

FIG. 15 is a flowchart of forming a stock solution in a method for manufacturing a cover plate provided by the present disclosure.

FIG. 16 is a schematic plan view of a display device provided by the present disclosure.

FIG. 17 is a schematic cross-sectional view of the display device along line A-A′ in FIG. 16.

### DETAILED DESCRIPTION

Various exemplary embodiments of the present disclosure will now be described in detail with reference to the accompanying drawings. It should be noted that, unless otherwise specifically stated, the relative arrangement of components and steps, numerical expressions, and numerical values set forth in these embodiments do not limit the scope of the present disclosure.

The following description of at least one exemplary embodiment is merely illustrative and should not be construed as limiting the present disclosure and its application or use in any way.

Techniques, methods, and devices known to those of ordinary skill in the relevant art may not be discussed in detail, but where appropriate, such techniques, methods, and devices should be regarded as part of the specification.

In all the examples shown and discussed herein, any specific values should be interpreted as merely illustrative and not as limiting. Thus, other examples of exemplary embodiments may have different values.

It should be noted that similar reference numerals and letters indicate similar items in the following drawings, and thus, once an item is defined in one drawing, it does not need further discussion in subsequent drawings.

In display products, reliability verification of display panels may include a copper rod friction test to verify the stability of mobile phones over prolonged screen usage. The test uses a copper rod that is drawn across the screen of illuminated display devices such as mobile phones at a certain speed, with the standard being that no localized bright spots or screen artifacts are allowed in mid-to-low grayscale regions. During the copper rod friction test on the display screen, the surface film layer of the cover plate in the display device typically includes perfluorinated compounds. The terminal groups of the material in the surface film layer of the cover plate are trifluoromethyl groups, which are composed of three carbon-fluorine bonds. The carbon-fluorine bond is a strong covalent bond, resulting in high electronegativity for the surface film layer of the cover plate. After friction with the copper rod, the cover plate's surface easily gains electrons, causing negative charges to accumulate on the cover plate's surface. These negative charges enter the interior of the display panel from the edge of the cover plate, leading to bright spots due to defects within the display panel.

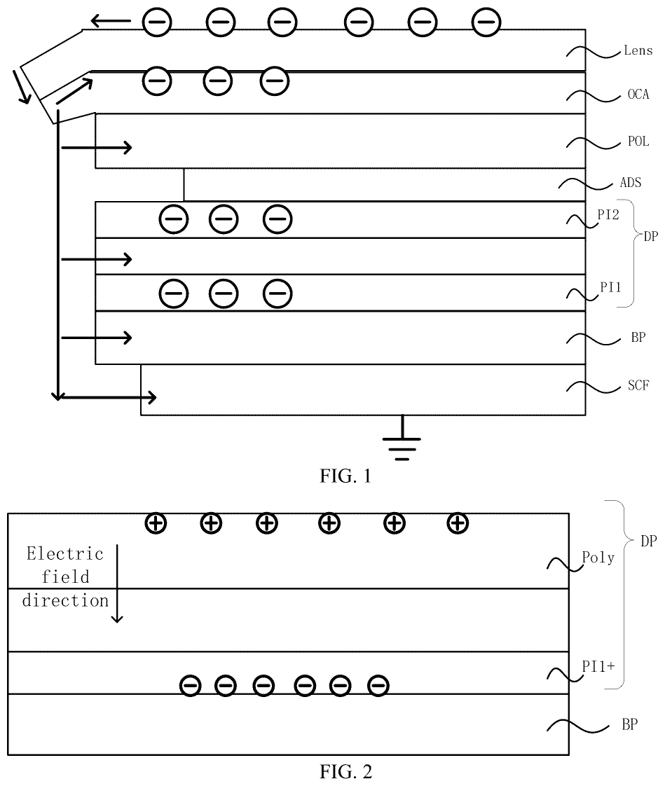

As shown in FIG. 1 and FIG. 2, FIG. 1 is a schematic diagram of a display device in the related art, and FIG. 2 is a schematic diagram of the principle of defect cause analysis in the related art. The display device includes a display panel (DP) and a lower protective film (BP). To enhance heat dissipation, a metal heat dissipation layer (SCF) is provided on the back side of the display panel. The display panel (DP) includes a substrate (PI1), a driving function layer, and a display function layer, which are arranged in a stacked manner. The driving function layer includes a passivation layer (PI2). The display device further includes an adhesive layer (ADS), a polarizer (POL), a glue layer (OCA), and a cover plate (Lens), which are arranged on the display function layer. After the copper rod friction on the cover plate (Lens), negative charges accumulate on the surface of the cover plate (Lens) and enter the interior of the display panel (DP) from the side of the display panel (DP). Due to the high resistance of the substrate (PI1) material, the negative charges migrate to the lower layer of the substrate (PI1) and accumulate. The electric field effect causes positive charges to shift upwards, resulting in a large electric field between the positive and negative charges. This electric field causes a small number of holes to accumulate in the active layer (Poly) and the substrate (PI1), forming a back-channel effect, which affects the characteristics of the thin-film transistors in the display panel, leading to a positive shift in the threshold voltage of the thin-film transistors and an increase in the sub-threshold swing, causing the display panel to appear brighter.

The present disclosure provides a cover plate, a method for manufacturing thereof, and a display device. This can solve the phenomenon of display anomalies caused by static electricity accumulation in existing display devices. The cover plate with the above technical effects provided by the present disclosure are described in detail as follows.

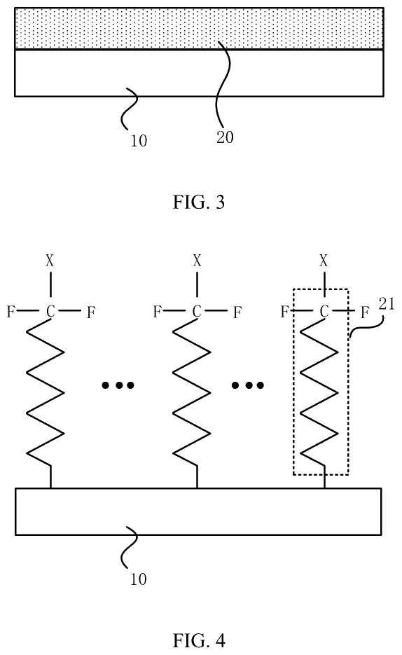

FIG. 3 is a schematic structural diagram of a cover plate provided by the present disclosure. FIG. 4 is a schematic diagram of a state where a compound having a first carbon chain is adsorbed on the surface of a substrate. Referring to FIG. 3 and FIG. 4, this embodiment provides a cover plate, which includes a substrate 10 and an antistatic film 20. The antistatic film 20 is located on a side of the substrate 10; and the antistatic film 20 includes a compound having a first carbon chain 21, and at least one carbon in the first carbon chain 21 carries an electron-donating group.

Specifically, the cover plate provided in this embodiment is used for a display device and may protect the display panel in the display device. The cover plate includes a substrate 10, which may be glass, such as ultra-ceramic glass, ultra-thin flat glass, ceramic, sapphire, etc., and may be 2D, 2.5D, or 3D covered. In some embodiments, the substrate 10 of the cover plate may define the front surface of the housing. In some embodiments, the substrate 10 of the cover plate may define the front surface and all or part of the side surface of the housing.

The cover plate further includes an antistatic film 20. The antistatic film 20 has anti-fingerprint and hydrophobic properties. The antistatic film 20 includes a compound having a first carbon chain 21, and at least one carbon in the first carbon chain 21 carries an electron-donating group X. The bond energy between the electron-donating group X and carbon is relatively weak, making the surface of the electron-donating group X easy to lose electrons during friction with objects such as metal, thus causing the surface of the antistatic film 20 to carry a positive charge. This effectively prevents the accumulation of negative charges on the surface of the antistatic film 20 during friction, thereby effectively improving the phenomenon of display anomalies caused by static electricity accumulation in existing display devices.

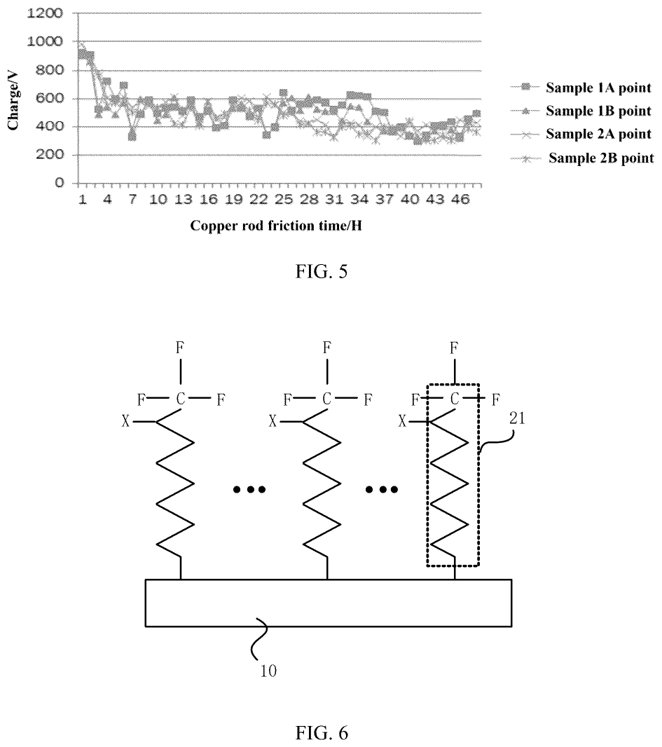

FIG. 5 is a simulation test diagram of a cover plate provided by the present disclosure after a copper rod friction test. Referring to FIG. 5, when conducting a copper rod friction test on the cover plate, the cover plate may become positively charged within 48 hours.

Optionally, continuing to refer to FIG. 3 and FIG. 4, the terminal group of the first carbon chain 21 carries an electron-donating group X. The electron-donating group X is set at the terminal group of the first carbon chain 21 and more easily loses electrons, thus causing the surface of the antistatic film 20 to carry a positive charge. In other embodiments of the present disclosure, referring to FIG. 6, FIG. 6 is a schematic diagram of another state where a compound having a first carbon chain is adsorbed on the surface of a substrate. The electron-donating group X may also be set at the secondary terminal group of the first carbon chain 21. It should be noted that in other embodiments of the present disclosure, the electron-donating group X may also be set on other carbons of the first carbon chain 21, and one carbon in the first carbon chain 21 may carry two or more electron-donating groups X. The present disclosure will not elaborate on this further.

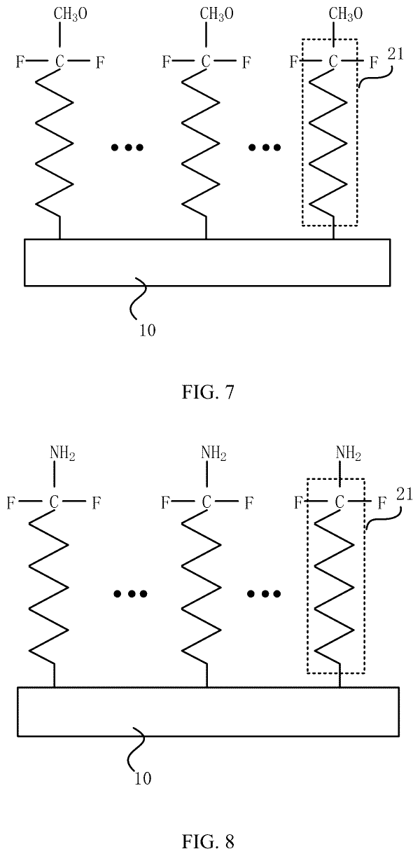

FIG. 7 is a schematic diagram of yet another state where a compound having a first carbon chain is adsorbed on the surface of a substrate. Referring to FIG. 3 and FIG. 7, in some optional embodiments, the electron-donating group X includes an alkoxy group. The bond energy between the alkoxy group and carbon is relatively weak, making the alkoxy group surface easy to lose electrons during friction with objects such as metals, thereby causing the surface of the antistatic film 20 to carry a positive charge. This effectively prevents the accumulation of negative charges on the surface of the antistatic film 20 during friction, thus effectively improving the phenomenon of display anomalies caused by static electricity accumulation in existing display devices.

FIG. 8 is a schematic diagram of yet another state where a compound having a first carbon chain is adsorbed on the surface of a substrate. Referring to FIG. 3 and FIG. 8, in some optional embodiments, the electron-donating group X includes an amino group. The bond energy between the amino group and carbon is relatively weak, making the amino group surface easy to lose electrons during friction with objects such as metals, thereby causing the surface of the antistatic film 20 to carry a positive charge. This effectively prevents the accumulation of negative charges on the surface of the antistatic film 20 during friction, thus effectively improving the phenomenon of display anomalies caused by static electricity accumulation in existing display devices.

It should be noted that this embodiment exemplarily shows that the electron-donating group X includes an alkoxy group or an amino group. In other embodiments of the present disclosure, the electron-donating group X may also include other groups that easily lose electrons. The present disclosure will not elaborate on this further.

Continuing to refer to FIG. 3 and FIG. 4, in some optional embodiments, at least one carbon in the first carbon chain 21 carries fluorine. The antistatic film 20 reacts and bonds with the substrate 10 through a carbon-fluorine bond. At least one carbon in the first carbon chain 21 carries fluorine, making the antistatic film 20 and the substrate 10 provide a firm bonding effect.

Optionally, except for the part of the carbons carrying the electron-donating group X, the rest of the first carbon chain 21 are carbon-fluorine bonds, making the antistatic film 20 and the substrate 10 have a firm bonding effect.

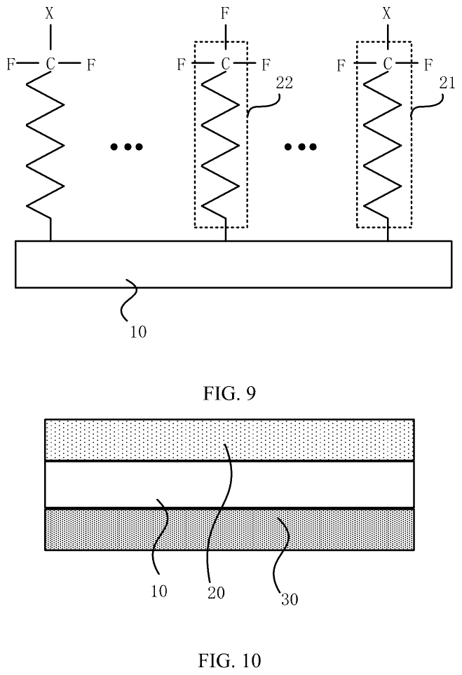

FIG. 9 is a schematic diagram of a state where a compound having a first carbon chain and a compound having a second carbon chain are adsorbed on the surface of a substrate. Referring to FIG. 3 and FIG. 9, in some optional embodiments, the antistatic film 20 includes a compound having a second carbon chain 22, where each carbon in the second carbon chain 22 carries fluorine.

Specifically, the antistatic film 20 reacts and bonds with the substrate 10 through a carbon-fluorine bond. The antistatic film 20 includes a compound having a second carbon chain 22, where each carbon in the second carbon chain 22 carries fluorine, making the antistatic film 20 and the substrate 10 have a firm bonding effect.

Continuing to refer to FIG. 3 and FIG. 9, in some optional embodiments, the first carbon chain 21 and the second carbon chain 22 have the same length. Therefore, when manufacturing a compound having the first carbon chain 21, it may be produced using a compound having the second carbon chain 22 by replacing the fluorine on at least one carbon of the second carbon chain 22 with an electron-donating group X. The manufacturing method is simple and effectively reduces production costs.

Continuing to refer to FIG. 3 and FIG. 9, in some optional embodiments, the first carbon chain 21 is uniformly distributed in the antistatic film.

Specifically, at least one carbon in the first carbon chain 21 carries an electron-donating group X. The bond energy between the electron-donating group X and carbon is relatively weak, making the surface of the electron-donating group X easy to lose electrons during friction with objects such as metals. The first carbon chain 21 is uniformly distributed in the antistatic film, causing the surface of the antistatic film 20 to carry a positive charge everywhere, effectively preventing the accumulation of negative charges on the surface of the antistatic film 20 during friction, thus effectively improving the phenomenon of display anomalies caused by static electricity accumulation in existing display devices.

FIG. 10 is a schematic structural diagram of another cover plate provided by the present disclosure. Referring to FIG. 10, in some optional embodiments, a cover plate further includes an ink layer 30, where the ink layer 30 is located on a side of a substrate 10 opposite to an antistatic film 20. The ink layer 30 is used to achieve alignment and bonding between the cover plate and the display panel. At the same time, the ink layer 30 may also shield light in the bezel region of the display panel, preventing light leakage.

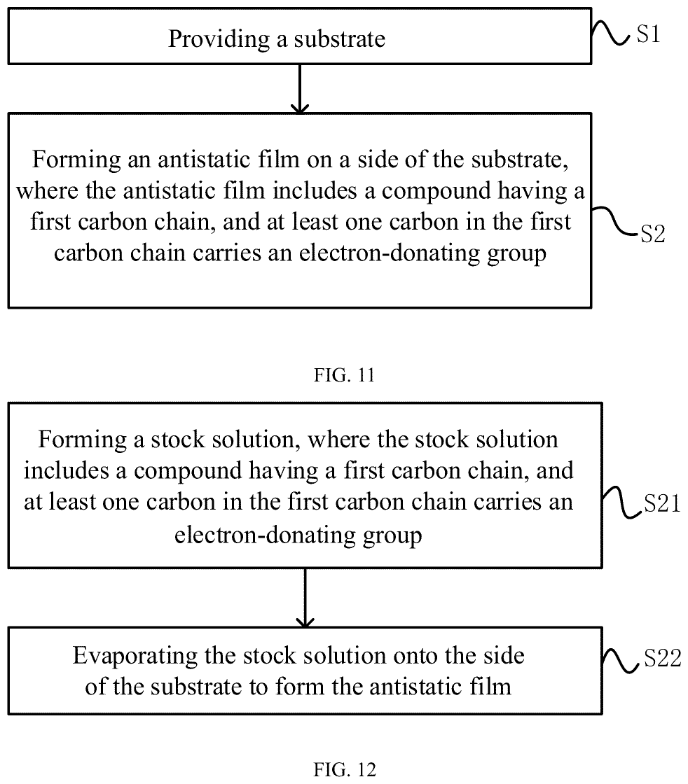

FIG. 11 is a flowchart of a method for manufacturing a cover plate provided by the present disclosure. Referring to FIG. 11, this embodiment provides a method for manufacturing a cover plate, including:
step S1: providing a substrate; and
step S2: forming an antistatic film on a side of the substrate, where the antistatic film includes a compound having a first carbon chain, and at least one carbon in the first carbon chain carries an electron-donating group.

Specifically, referring to FIG. 3, FIG. 4 and FIG. 11, the cover plate manufactured using the method provided in this embodiment is used for a display device and may protect the display panel in the display device. The cover plate includes a substrate 10, which may be glass, such as ultra-ceramic glass, ultra-thin flat glass, ceramic, sapphire, etc., and may be 2D, 2.5D, or 3D covered. In some embodiments, the substrate 10 of the cover plate may define the front surface of the housing. In some embodiments, the substrate 10 of the cover plate may define the front surface and all or part of the side surface of the housing.

The cover plate further includes an antistatic film 20. The antistatic film 20 has anti-fingerprint and hydrophobic properties. The antistatic film 20 includes a compound having a first carbon chain 21, and at least one carbon in the first carbon chain 21 carries an electron-donating group X. The bond energy between the electron-donating group X and carbon is relatively weak, making the surface of the electron-donating group X easy to lose electrons during friction with objects such as metals. This causes the surface of the antistatic film 20 to carry a positive charge, effectively preventing the accumulation of negative charges on the surface of the antistatic film 20 during friction, thus effectively improving the phenomenon of display anomalies caused by static electricity accumulation in existing display devices.

In some optional embodiments, the electron-donating group includes an alkoxy group or an amino group.

Referring to FIG. 3 and FIG. 7, in some optional embodiments, the electron-donating group X includes an alkoxy group. The bond energy between the alkoxy group and carbon is relatively weak, making the alkoxy group surface easy to lose electrons during friction with objects such as metals. This causes the surface of the antistatic film 20 to carry a positive charge, effectively preventing the accumulation of negative charges on the surface of the antistatic film 20 during friction, thus effectively improving the phenomenon of display anomalies caused by static electricity accumulation in existing display devices.

Referring to FIG. 3 and FIG. 8, in some optional embodiments, the electron-donating group X includes an amino group. The bond energy between the amino group and carbon is relatively weak, making the amino group surface easy to lose electrons during friction with objects such as metals. This causes the surface of the antistatic film 20 to carry a positive charge, effectively preventing the accumulation of negative charges on the surface of the antistatic film 20 during friction, thus effectively improving the phenomenon of display anomalies caused by static electricity accumulation in existing display devices.

It should be noted that this embodiment exemplarily shows that the electron-donating group X includes an alkoxy group or an amino group. In other embodiments of the present disclosure, the electron-donating group X may also include other groups that easily lose electrons. The present disclosure will not elaborate on this further.

FIG. 12 is a flowchart of forming an antistatic film on a side of a substrate in a method for manufacturing a cover plate provided by the present disclosure. Referring to FIG. 11 and FIG. 12, in some optional embodiments, forming an antistatic film on a side of a substrate in step S2 includes:
step S21: forming a stock solution, where the stock solution includes a compound having a first carbon chain, and at least one carbon in the first carbon chain carries an electron-donating group; and
step S22: evaporating the stock solution onto the side of the substrate to form the antistatic film.

Specifically, in the method for manufacturing the cover plate, a stock solution including a compound having a first carbon chain may first be formed, and at least one carbon in the first carbon chain carries an electron-donating group. The stock solution is then evaporated onto a side of the substrate to form the antistatic film on the side of the substrate. The manufacturing method is simple.

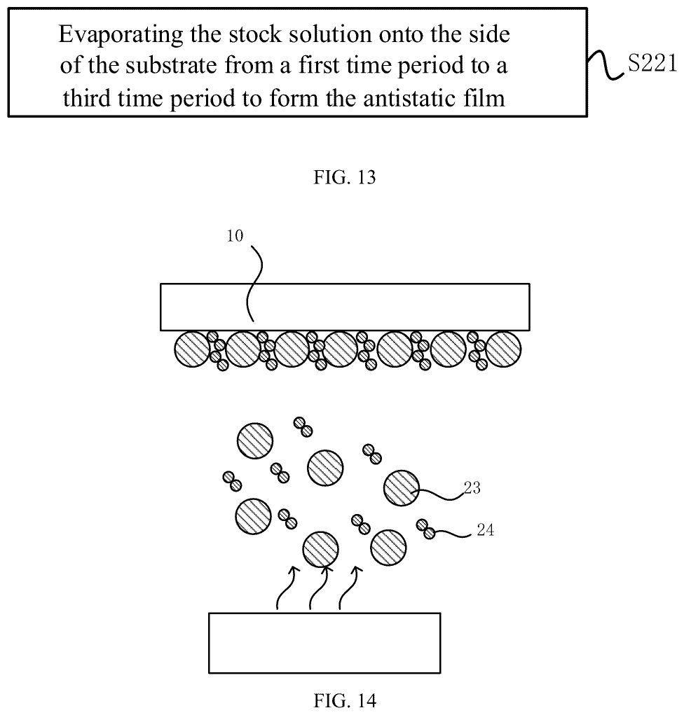

FIG. 13 is a flowchart of forming an antistatic film by evaporating a stock solution onto a side of a substrate in a method for manufacturing a cover plate provided by the present disclosure. Referring to FIGS. 11-13, in some optional embodiments, evaporating the stock solution onto the side of the substrate to form the antistatic film in step S22, includes:
step S221: evaporating the stock solution onto the side of the substrate from a first time period to a third time period to form the antistatic film, where:
during the first time period, the evaporation rate of the stock solution gradually increases to a first rate;
during the second time period, the evaporation rate of the stock solution is maintained at the first rate; and
during the third time period, the evaporation rate of the stock solution decreases from the first rate to zero.

Specifically, the stock solution includes positive group macromolecules and conventional group small molecules. Compared to positive group macromolecules, conventional group small molecules have a lighter mass. Using the conventional evaporation method, where the evaporation rate increases to the peak and then immediately decreases, conventional group small molecules are more likely to evaporate onto the substrate surface and occupy effective binding sites. In contrast, positive group macromolecules evaporate more slowly and can only crosslink with the remaining binding potentials, leading to uneven distribution of the antistatic film on the substrate and poor uniformity of the antistatic film formed by evaporation on the substrate.

Referring to FIGS. 11-14, FIG. 14 is a schematic diagram of the process of evaporating a stock solution onto a side of a substrate to form an antistatic film. In this embodiment, during a first time period, an evaporation rate of the stock solution gradually increases to a first rate; during a second time period, the evaporation rate of the stock solution is maintained at the first rate; and during a third time period, the evaporation rate of the stock solution decreases from the first rate to zero. That is, the evaporation rate increases to the peak, is maintained for a period of time, and then decreases. Thus, during the evaporation process, the evaporation rates of the positive group macromolecules 23 and conventional group small molecules 24 tend to be the same, causing the positive group macromolecules 23 and conventional group small molecules 24 to crosslink simultaneously with the substrate 10. This ensures that the antistatic film is uniformly distributed on the substrate, effectively improving the uniformity of the antistatic film. Consequently, when rubbed by objects such as metals, the surface of the antistatic film 20 is uniformly positively charged, effectively preventing the accumulation of negative charges on the surface of the antistatic film 20 during friction, thereby effectively improving the phenomenon of display anomalies caused by static electricity accumulation in existing display devices.

In some optional embodiments, the first rate is 3 Å/S.

Specifically, during the first time period, the evaporation rate of the stock solution gradually increases to 3 Å/S; during the second time period, the evaporation rate of the stock solution is maintained at 3 Å/S; and during the third time, the evaporation rate of the stock solution decreases from 3 Å/S to zero. Thus, during the evaporation process, the evaporation rates of the positive group macromolecules 23 and conventional group small molecules 24 tend to be the same, while also avoiding excessive evaporation rates of the stock solution, which would waste resources.

It should be noted that this embodiment exemplarily shows the first rate as 3 Å/S. In other embodiments of the present disclosure, the specific setting of the first rate may be adjusted to other values based on production needs. The present disclosure will not elaborate on this further.

In some optional embodiments, the first time period is from minute 1 to minute 2 (e.g., including the first two minutes), the second time period is minute 2 to minute 4, and the third time period is after minute 4.

For example, in the first two minutes, that is from time point of first minute to time point of second minute, the evaporation rate of the stock solution gradually increases to the first rate; from time point of the second minute to time point of the fourth minute, the evaporation rate of the stock solution is maintained at the first rate; and after time point of fourth minute, the evaporation rate of the stock solution decreases from the first rate to zero. It avoids that the evaporation time for the stock solution is too short, which would prevent the evaporation rates of the positive group macromolecules 23 and conventional group small molecules 24 from tending to be the same. At the same time, it avoids that an evaporation time for the stock solution is too long, which would waste resources.

It should be noted that this embodiment exemplarily shows the first time period includes the first two minutes, the second time period includes the following two minutes, and the third time period includes time period after the fourth minute. In other embodiments of the present disclosure, the specific setting of the first time period, second time period, and third time period may be adjusted to other values based on production needs.

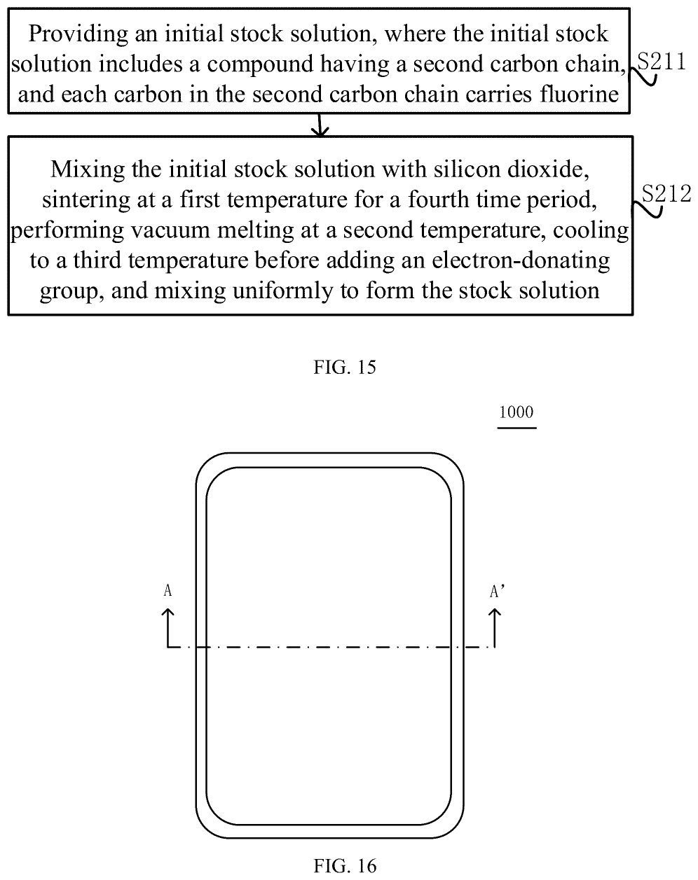

FIG. 15 is a flowchart of forming a stock solution in a method for manufacturing a cover plate provided by the present disclosure. Referring to FIG. 11, FIG. 12, and FIG. 15, in some optional embodiments, forming the stock solution in step S21 includes:
step S211: providing an initial stock solution, where the initial stock solution includes a compound having a second carbon chain, and each carbon in the second carbon chain carries fluorine; and
step S212: mixing the initial stock solution with silicon dioxide, sintering at a first temperature for a fourth time period, performing vacuum melting at a second temperature, cooling to a third temperature before adding an electron-donating group, and mixing uniformly to form the stock solution.

Where, the first temperature is lower than the second temperature, and the third temperature is lower than the first temperature.

Specifically, the initial stock solution is first provided, and the initial stock solution includes a compound having a second carbon chain, where each carbon in the second carbon chain carries fluorine. The initial stock solution is mixed with silicon dioxide, sintered at the first temperature for the fourth time, vacuum melted at the second temperature, and then cooled to the third temperature. After cooling, the electron-donating group is added and mixed uniformly, replacing at least one carbon carrying fluorine in the second carbon chain with the electron-donating group, thus forming the stock solution. The stock solution includes a compound having a first carbon chain, and at least one carbon in the first carbon chain carries an electron-donating group. Consequently, after evaporating the stock solution onto a side of a substrate to form an antistatic film, the antistatic film includes the compound having the first carbon chain, and at least one carbon in the first carbon chain carries the electron-donating group. The manufacturing method is simple and effectively reduces production costs.

In some optional embodiments, the first temperature is 1000° C., the second temperature is 1300° C., and the fourth time period is 4-6 hours.

It should be noted that this embodiment exemplarily shows the first temperature as 1000° C., the second temperature as 1300° C., and the fourth time period as 4-6 hours. In other embodiments of the present disclosure, the specific setting of the first temperature, the second temperature, and the fourth time period may be adjusted to other values based on production needs. The present disclosure will not elaborate on this further.

This embodiment provides a display device, which includes a display panel and a cover plate. The cover plate is located on a light-emitting side of the display panel, where the cover plate is the cover plate provided by the present disclosure, and an antistatic film is located on a side of a substrate away from the display panel.

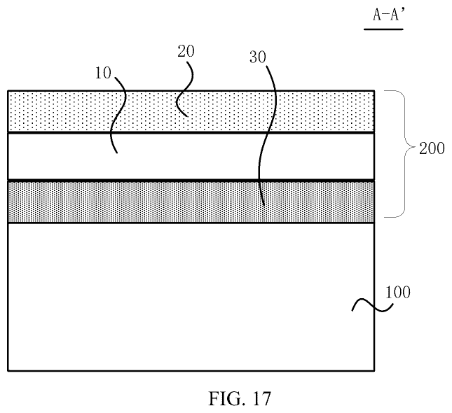

Referring to FIG. 16 and FIG. 17, FIG. 16 is a schematic plan view of a display device provided by the present disclosure, and FIG. 17 is a schematic cross-sectional view of the display device along line A-A′ in FIG. 16. The display device 1000 includes a display panel 100 and a cover plate 200. The cover plate 200 is the cover plate provided by any of the above embodiments of the present disclosure. In the cover plate 200, an antistatic film 20 is located on a side of a substrate 10 away from the display panel 100.

FIG. 16 and FIG. 17 take a mobile phone as an example to explain the display device 1000. It should be understood that the display device provided by the embodiments of the present disclosure may be other display devices with display functions, such as computers, televisions, vehicle-mounted display devices, etc. The present disclosure does not specifically limit this. The display device provided by the embodiments of the present disclosure has the beneficial effects of the cover plate provided by the embodiments of the present disclosure. Specific details of the cover plate can be referred to in the above embodiments and will not be repeated here.

Through the above embodiments, it can be seen that the cover plate and its manufacturing method, as well as the display device provided by the present disclosure, at least achieve the following beneficial effects:

The cover plate provided by the present disclosure includes an antistatic film. The antistatic film includes a compound having a first carbon chain, and at least one carbon in the first carbon chain carries an electron-donating group. The bond energy between the electron-donating group and carbon is relatively weak, making the surface of the electron-donating group easy to lose electrons during friction with objects such as metals. This causes the surface of the antistatic film to carry a positive charge, effectively preventing the accumulation of negative charges on the surface of the antistatic film during friction, thus effectively improving the phenomenon of display anomalies caused by static electricity accumulation in existing display devices.

Although some specific embodiments of the present disclosure have been described in detail through examples, those skilled in the art should understand that these examples are only for illustration purposes and are not intended to limit the scope of the present disclosure. Those skilled in the art should understand that modifications can be made to the above embodiments without departing from the scope and spirit of the present disclosure. The scope of the present disclosure is defined by the appended claims.

What is claimed is:

1. A cover plate, comprising a substrate and an antistatic film, wherein the antistatic film is located on a side of the substrate, the antistatic film comprises a compound having a first carbon chain, and at least one carbon in the first carbon chain carries an electron-donating group.

2. The cover plate according to claim 1, wherein the electron-donating group comprises an alkoxy group or an amino group.

3. The cover plate according to claim 1, wherein the at least one carbon in the first carbon chain carries fluorine.

4. The cover plate according to claim 2, wherein the antistatic film comprises a compound having a second carbon chain, and each carbon in the second carbon chain carries fluorine.

5. The cover plate according to claim 4, wherein the first carbon chain and the second carbon chain have a same length.

6. The cover plate according to claim 1, wherein the first carbon chain is uniformly distributed in the antistatic film.

7. The cover plate according to claim 1, further comprising an ink layer, wherein the ink layer is located on a side of the substrate opposite to the antistatic film.

8. A method for manufacturing a cover plate, comprising:
providing a substrate; and
forming an antistatic film on a side of the substrate, wherein the antistatic film comprises a compound having a first carbon chain, and at least one carbon in the first carbon chain carries an electron-donating group.

9. The method according to claim 8, wherein the electron-donating group comprises an alkoxy group or an amino group.

10. The method according to claim 8, wherein forming the antistatic film on the side of the substrate comprises:
forming a stock solution, wherein the stock solution comprises the compound having the first carbon chain, and the at least one carbon in the first carbon chain carries the electron-donating group; and
evaporating the stock solution onto the side of the substrate to form the antistatic film.

11. The method according to claim 10, wherein evaporating the stock solution onto the side of the substrate to form the antistatic film comprises evaporating the stock solution onto the side of the substrate during three time periods, wherein:
during a first time period, an evaporation rate of the stock solution gradually increases to a first rate;
during a second time period, the evaporation rate of the stock solution is maintained at the first rate; and
during a third time period, the evaporation rate of the stock solution decreases from the first rate to zero.

12. The method according to claim 11, wherein the first rate is 3 Å/S.

13. The method according to claim 11, wherein the first time period is from minute one to minute two, the second time period is from minute two to minute four, and the third time period is after minute four.

14. The method according to claim 10, wherein forming the stock solution comprises:
providing an initial stock solution, wherein the initial stock solution comprises a compound having a second carbon chain, and each carbon in the second carbon chain carries fluorine; and
mixing the initial stock solution with silicon dioxide, sintering at a first temperature for a fourth time period, vacuum melting at a second temperature, cooling to a third temperature, adding the electron-donating group, and mixing uniformly to form the stock solution, wherein the first temperature is lower than the second temperature, and the third temperature is lower than the first temperature.

15. The method according to claim 14, wherein the first temperature is 1000° C., the second temperature is 1300° C., and the fourth time period is 4-6 hours.

16. A display device, comprising a display panel and a cover plate, wherein the cover plate is located on a light-emitting side of the display panel; and the cover plate comprises a substrate and an antistatic film, wherein the antistatic film is located on a side of the substrate away from the display panel, the antistatic film comprises a compound having a first carbon chain, and at least one carbon in the first carbon chain carries an electron-donating group.
